(19) United States
(12) Patent Application Publication
(10) Pub. No.: US 2026/0204482 A1
(43) Pub. Date: Jul. 16, 2026

(54) MULTILAYER ELECTRONIC COMPONENT

(71) Applicant: SAMSUNG ELECTRO-MECHANICS CO., LTD., Suwon-si (KR)

(72) Inventor: Ye Jin JEONG, Suwon-si (KR)

(73) Assignee: SAMSUNG ELECTRO-MECHANICS CO., LTD., Suwon-si (KR)

(21) Appl. No.: 19/392,808

(22) Filed: Nov. 18, 2025

(30) Foreign Application Priority Data
Jan. 10, 2025 (KR) 10-2025-0004024

(51) Int. Cl. H01G 4/232; H01G 2/06; H01G 4/008; H01G 4/012; H01G 4/30

(52) U.S. Cl. CPC H01G 4/2325; H01G 2/065; H01G 4/008; H01G 4/012; H01G 4/30

(57) ABSTRACT

A multilayer electronic component includes a body including a dielectric layer, and a first internal electrode and a second internal electrode disposed alternately with the dielectric layer interposed therebetween, and a first external electrode and a second external electrode disposed on the body and connected to the first and second internal electrodes, respectively. The first external electrode is provided with a tin (Sn) plating layer disposed on an outermost portion thereof, and the second external electrode is provided with a gold-tin (Au—Sn) plating layer having a different color from a color of the Sn plating layer, disposed on an outermost thereof.

### CROSS-REFERENCE TO RELATED APPLICATION(S)

This application claims benefit of priority to Korean Patent Application No. 10-2025-0004024 filed on Jan. 10, 2025 in the Korean Intellectual Property Office, the disclosure of which is incorporated herein by reference in its entirety.

### TECHNICAL FIELD

The present disclosure relates to a multilayer electronic component.

Multilayer ceramic capacitors (MLCCs), a type of multilayer electronic component, are chip-shaped capacitors that are mounted on the printed circuit boards of various electronic products such as video devices of Liquid Crystal Displays (LCDs) and Plasma Display Panels (PDPs), computers, smartphones, and mobile phones to charge or discharge electricity therein or therefrom. MLCCs are used as components of various electronic devices due to their advantages of being small, having high capacity, and being easy to mount.

Meanwhile, screening tests, such as burn-in testing, are conducted to induce potential defects in MLCCs and preemptively screen for early defects. During screening tests, high voltage is applied to the MLCCs repeatedly, and the voltage continues to be applied to MLCCs even after final screening and mounting on the printed circuit board. MLCCs typically have two external electrodes, which are typically indistinguishable from each other visually. Therefore, the voltage application direction may change multiple times during screening testing, which may degrade the insulation resistance (IR) and lifespan characteristics of the dielectric. Therefore, unifying the voltage application direction during MLCC screening testing and final use may improve MLCC reliability.

### SUMMARY

An aspect of the present disclosure is to provide a multilayer electronic component having excellent reliability.

According to an aspect of the present disclosure, a multilayer electronic component includes a body including a dielectric layer, and a first internal electrode and a second internal electrode disposed alternately with the dielectric layer interposed therebetween, and a first external electrode and a second external electrode disposed on the body and connected to the first and second internal electrodes, respectively. The first external electrode is provided with a tin (Sn) plating layer disposed on an outermost portion thereof, and the second external electrode is provided with a gold-tin (Au—Sn) plating layer having a different color from a color of the Sn plating layer, disposed on an outermost thereof.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view schematically illustrating a multilayer electronic component according to an embodiment,

FIG. 2 is a cross-sectional view schematically illustrating a cross-section taken along line I-I′ of FIG. 1;

FIG. 3 is a cross-sectional view schematically illustrating a cross-section taken along line II-II′ of FIG. 1;

FIG. 4 is a cross-sectional view schematically illustrating a cross-section taken along line III-III′ of FIG. 1;

FIG. 5 is a cross-sectional view schematically illustrating a multilayer electronic component according to another embodiment, corresponding to FIG. 2;

FIG. 6 is a plan view schematically illustrating a multilayer electronic component packaging unit according to an embodiment;

FIG. 7A is a graph illustrating the life Weibull distributions of Examples 1 and 2;

FIG. 7B is a graph illustrating the life Weibull distributions of Examples 3 and 4; and

FIG. 7C is a graph illustrating the life Weibull distributions of Examples 5 and 6.

### DETAILED DESCRIPTION

Hereinafter, embodiments of the present disclosure will be described with reference to detailed embodiments and accompanying drawings. However, the embodiments of the present disclosure may be modified in many different forms, and the scope of the present disclosure is not limited to the embodiments described below. In addition, the embodiments of the present disclosure are provided to more completely describe the present disclosure to those skilled in the art. Therefore, the shape and size of elements in the drawings may be exaggerated for clearer explanation, and elements indicated by the same reference numerals in the drawings are the same elements.

In addition, to clearly describe the present disclosure in the drawings, parts irrelevant to the description are omitted, and the size and thickness of each component illustrated in the drawings are arbitrarily illustrated for convenience of description, and thus, the present disclosure is not necessarily limited to the illustrated embodiment. Also, components having the same function within the scope of the same concept are described using the same reference numerals. Furthermore, throughout the specification, when a certain component is said to “include,” it means that it may further include other components without excluding other components unless otherwise stated.

In the drawings, the first direction (X) may be defined as the thickness (T) direction, the second direction (Y) as the length (L) direction, and the third direction (Z) as the width (W) direction.

### Multilayer Electronic Component

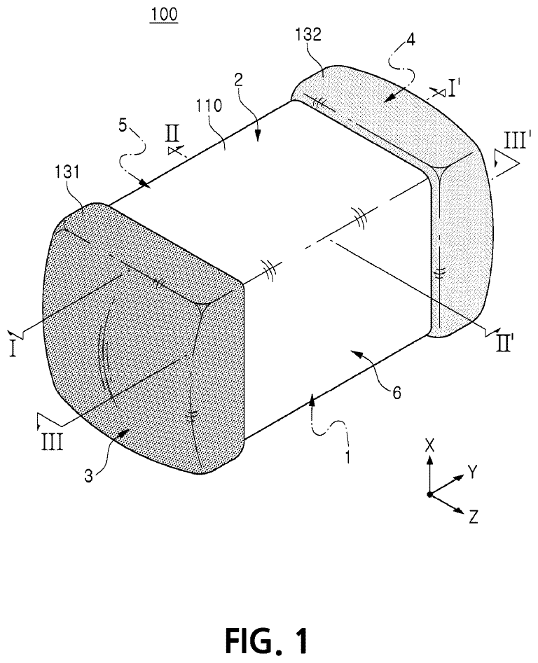

FIG. 1 is a perspective view schematically illustrating a multilayer electronic component according to an embodiment.

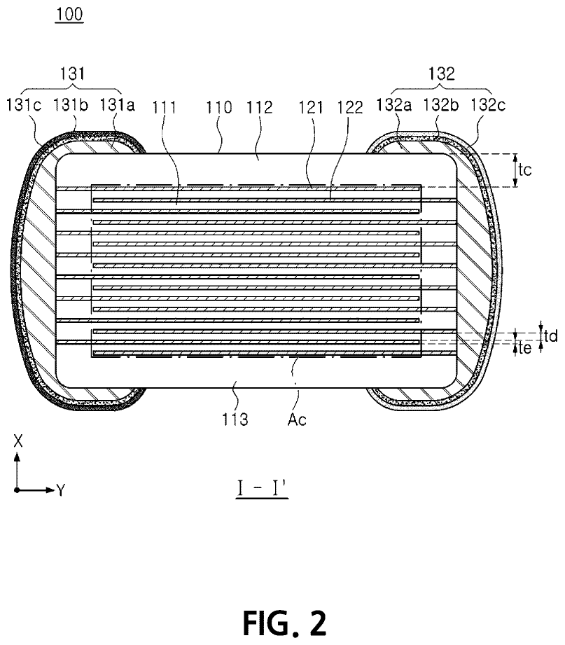

FIG. 2 is a cross-sectional view schematically illustrating a cross-section taken along line I-I′ of FIG. 1.

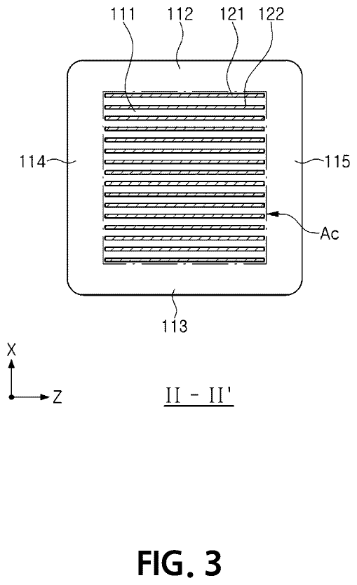

FIG. 3 is a cross-sectional view schematically illustrating a cross-section taken along line II-II′ of FIG. 1.

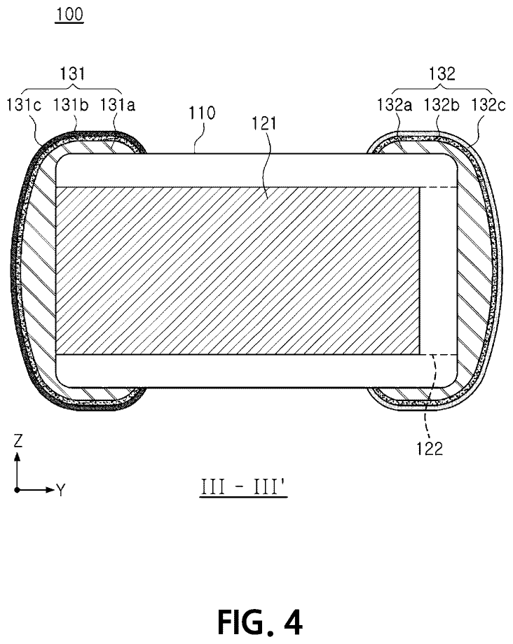

FIG. 4 is a cross-sectional view schematically illustrating a cross-section taken along line III-III′ of FIG. 1.

Hereinafter, a multilayer electronic component 100 according to an embodiment will be described in detail with reference to FIGS. 1 through 4. Furthermore, while a multilayer ceramic capacitor is described as an example of a multilayer electronic component, the present disclosure is not limited thereto and may be applied to various multilayer electronic components, such as inductors, piezoelectric elements, varistors, or thermistors.

A multilayer electronic component 100 according to an embodiment may include a body 110 and external electrodes 131 and 132 disposed on the body 110.

While there are no specific limitations on the detailed shape of the body 110, as illustrated, the body 110 may be formed in a hexahedral shape or a similar shape. Due to shrinkage of the ceramic powder contained in the body 110 during the sintering process or due to a polishing process on the edges of the body 110, the body 110 may not be a perfectly straight hexahedral shape, but may have a substantially hexahedral shape.

The body 110 may have first and second surfaces 1 and 2 opposing each other in the first direction, third and fourth surfaces 3 and 4 connected to the first and second surfaces 1 and 2 and opposing each other in the second direction, and fifth and sixth surfaces 5 and 6 connected to the first to fourth surfaces 1, 2, 3 and 4 and opposing each other in the third direction.

The body 110 may include a dielectric layer 111 and internal electrodes 121 and 122 disposed alternately with the dielectric layer 111. The plurality of dielectric layers 111 forming the body 110 are in a sintered state, and the boundaries between adjacent dielectric layers 111 may be so integrated that they are difficult to discern without a scanning electron microscope (SEM).

The dielectric layer 111 may, for example, include a perovskite-type compound represented by ABO₃ as the main component thereof. The perovskite compound represented by ABO₃ may include at least one, for example, selected from the group consisting of BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), Ba(Ti_{1-y}Zr_{y})O₃ (0<y<1), CaZrO₃ and (Ca₁₋ₓSrₓ)(Zr_{1-y}Ti_{y})O₃ (0<x≤0.5, 0<y≤0.5).

The average thickness (td) of the dielectric layer 111 is not particularly limited. The average thickness (td) of the dielectric layer 111 may be, for example, 0.1 μm to 20 μm, 0.1 μm to 10 μm, 0.1 μm to 5 μm, 0.1 μm to 2 μm, or 0.1 μm to 0.4 μm.

The internal electrodes 121 and 122 may include, for example, a first internal electrode 121 and a second internal electrode 122 that are alternately disposed in the first direction with a dielectric layer 111 interposed therebetween. The first internal electrode 121 and the second internal electrode 122, which are a pair of electrodes with different polarities, may be disposed to face each other with the dielectric layer 111 interposed therebetween.

The first internal electrode 121 may be spaced apart from the fourth surface 4 and connected to the first external electrode 131 at the third surface 3. The second internal electrode 122 may be spaced apart from the third surface 3 and connected to the second external electrode 132 at the fourth surface 4.

The conductive metal included in the internal electrodes 121 and 122 may be at least one selected from the group consisting of Ni, Cu, Pd, Ag, Au, Pt, Sn, W, Ti, and alloys thereof, and in more detail, include Ni, but the present disclosure is not limited thereto.

The average thickness (te) of the internal electrodes 121 and 122 is not particularly limited. The average thickness (te) of the internal electrodes 121 and 122 may be, for example, 0.1 μm to 3.0 μm, 0.1 μm to 1.0 μm, or 0.1 μm to 0.4 μm.

The average thickness (td) of the dielectric layer 111 and the average thickness (te) of the internal electrodes 121 and 122 refer to the average thicknesses of the dielectric layer 111 and the internal electrodes 121 and 122 in the first direction, respectively. The average thickness (td) of the dielectric layer 111 and the average thickness (te) of the internal electrodes 121 and 122 may be measured by scanning the first and second direction cross-section of the body 110 with a scanning electron microscope (SEM) at 10,000× magnification. In more detail, the average thickness (td) of the dielectric layer 111 may be measured by measuring the thickness at multiple points on a single dielectric layer 111, for example, five equally spaced points in the X-direction, and then taking the average value. Additionally, the average thickness (te) of the internal electrodes 121 and 122 may be measured by measuring the thickness at multiple points on a single internal electrode 121 or 122, for example, at five equally spaced points in the second direction, and then taking the average value. The five equally spaced points may be designated in the capacitance forming portion (Ac). Furthermore, by performing the measurement of these average values for each of the ten dielectric layers 111 and ten internal electrodes 121 and 122, and then taking the average values, the average thickness (td) of the dielectric layer 111 and the average thickness (te) of the internal electrodes 121 and 122 may be more generalized.

The body 110 may include a capacitance formation portion (Ac) which is disposed within the body 110 and in which capacitance is formed, including first and second internal electrodes 121 and 122 disposed alternately with the dielectric layer 111 interposed therebetween, cover portions 112 and 113 disposed on both surfaces of the capacitance formation portion (Ac) opposing each other in the first direction, and margin portions 114 and 115 disposed on both surfaces of the capacitance formation portion (Ac) opposing each other in the third direction. The cover portions 112 and 113 and the margin portions 114 and 115 may have a similar configuration to the dielectric layer 111, except that they do not include an internal electrode.

The average thickness (tc) of the cover portions 112 and 113 may be, for example, 300 μm or less, 150 μm or less, 100 μm or less, 30 μm or less, or 20 μm or less. The average thickness (tc) of the cover portions 112 and 113 may be, for example, 5 μm or more, 10 μm or more, or 30 μm or more. In this case, the average thickness (tc) of the cover portions 112 and 113 refers to the average thickness of each of the first cover portion 112 and the second cover portion 113.

The average thickness (tc) of the cover portions 112 and 113 may refer to the average thickness of the cover portions 112 and 113 in the first direction, and may be the average of the thicknesses in the first direction measured at five equally spaced points on the cross-section of the body 110 in the first and second directions.

The average thickness of the margin portions 114 and 115 may be, for example, 150 μm or less, 100 μm or less, 20 μm or less, or 15 μm or less. The average thickness of the margin portions 114 and 115 may be, for example, 5 μm or more, 10 μm or more, or 20 μm or more. In this case, the average thickness of the margin portions 114 and 115 refers to the average thickness of each of the first margin portion 114 and the second margin portion 115.

The average thickness of the margin portions 114 and 115 may refer to the average thickness of the margin portions 114 and 115 in the third direction, and may be an average value of the thicknesses in the third direction measured at five equally spaced points in the first direction and third-direction cross section of the body 110.

The external electrodes 131 and 132 may include first and second external electrodes 131 and 132 connected to the first and second internal electrodes 121 and 122, respectively. The first external electrode 131 may be disposed on the third surface 3 to contact an end of the first internal electrode 121, and the second external electrode 132 may be disposed on the fourth surface 4 to contact an end of the second internal electrode 122. The first external electrode 131 may extend from the third surface 3 to portions of the first, second, fifth, and sixth surfaces 1, 2, 5 and 6, and the second external electrode 132 may extend from the fourth surface 4 to portions of the first, second, fifth, and sixth surfaces 1, 2, 5 and 6.

According to an embodiment, a Sn plating layer 131c may be disposed on the outermost surface of the first external electrode 131, and a Au—Sn plating layer 132c having a different color from the Sn plating layer 131c may be disposed on the outermost surface of the second external electrode 132.

As described above, after manufacturing, a multilayer electronic component undergoes screening test, such as a burn-in test. During the screening test, a high voltage should be applied to the multilayer electronic component several times. However, if the appearance of the first external electrode and the appearance of the second external electrode are indistinguishable, the voltage application direction to the multilayer electronic component may change several times during the selection process and subsequent use.

When voltage is applied to the dielectric, the domains within the dielectric may be aligned in the direction of the voltage application. Subsequent heat treatment of the dielectric may re-arrange the domains randomly, but some domains may remain aligned in their original alignment even after the heat treatment. In this state, if a voltage is applied to the dielectric in the opposite direction, some domains may be damaged by the voltage applied in the opposite direction to the alignment direction, which may degrade the insulation resistance of the dielectric.

Meanwhile, in the case of the multilayer electronic component 100 according to an embodiment of the present disclosure, a Sn plating layer 131c is disposed on the outermost surface of the first external electrode 131, and a Au—Sn plating layer 132c having a different color from the Sn plating layer 131c is disposed on the outermost surface of the second external electrode 132, thereby allowing the first external electrode 131 and the second external electrode 132 to be distinguished during the selection process and use. This unifies the voltage application direction to the multilayer electronic component 100 during the selection process and use, thereby improving the reliability of the multilayer electronic component 100.

In the present disclosure, the fact that the Sn plating layer 131c and the Au—Sn plating layer 132c have different colors may indicate, for example, that the color difference (ΔE) between the Sn plating layer 131c and the Au—Sn plating layer 132c, defined by the following mathematical formula 1, is 50 or more.

ΔE=[(ΔL*)²+(Δa*)²+(Δb*)²]^{1/2} [Mathematical Formula 1]

In the above Mathematical Formula 1, ΔL* may refer to the difference between the L* value of the CIE L*a*b* colorimetric system measured in the Sn plating layer 131c and the L* value measured in the Au—Sn plating layer 132c, Δa* may refer to the difference between the a* value of the CIE L*a*b* colorimetric system measured in the Sn plating layer 131c and the a* value measured in the Au—Sn plating layer 132c, and Δb* may refer to the difference between the b* value of the CIE L*a*b* colorimetric system measured in the Sn plating layer 131c and the b* value measured in the Au—Sn plating layer 132c. In the present disclosure, the “CIE L*a*b* colorimetric system” may mean the colorimetric system standardized and recommended by CIE in 1976.

Meanwhile, the Au—Sn plating layer 132c may include an Au—Sn alloy including Au, which is a colored metal but has excellent electrical conductivity and has solderability that is not much inferior to that of Sn, and Sn, which has excellent solderability. The Au—Sn plating layer 132c may be sufficient if it includes an Au—Sn alloy. However, for example, the Au content (wt %) relative to the total elements in the Au—Sn plating layer 132c may be greater than the Sn content (wt %) relative to the total elements in the Au—Sn plating layer 132c. This allows for a more reliable distinction between the first external electrode 131 and the second external electrode 132. Since Au has excellent wettability to Sn, even if the Au content (wt %) in the Au—Sn plating layer 132c is greater than the Sn content (wt %), mounting stability may not be significantly reduced.

In an embodiment, the Au content (wt %) relative to the total Au and Sn content in the Au—Sn plating layer 132c may be 62.4 wt % or more and less than 100 wt %. When this range is satisfied, the first external electrode 131 and the second external electrode 132 may be more clearly distinguished. Referring to Table 1 below, when the content (wt %) of Au compared to the total content of Au and Sn is 62.4 wt % or more, AuSn and/or Au₅Sn, which have a high proportion of Au among the intermetallic compounds between Au and Sn, may be formed, so that a color difference between the Sn plating layer 131c and the Au—Sn plating layer 132c may be clearly observed.

TABLE 1

| | |
|---|---|
| IMC | Weight Ratio (wt %) |

| Compound | Au | Sn |
|---|---|---|
| Au₅Sn | 89.2 | 10.8 |
| AuSn | 62.4 | 37.6 |
| AuSn₂ | 45.3 | 54.7 |
| AuSn₄ | 29.3 | 70.7 |

For example, when the b* value of the CIE L*a*b* colorimetric system measured on the Sn plating layer 131c is b₁* and the b* value of the CIE L*a*b* colorimetric system measured on the Au—Sn plating layer 132c is b₂*, the condition b₂*−b₁*≥50 may be satisfied.

Therefore, when performing the taping packaging process for the multilayer electronic component 100, a plurality of multilayer electronic components 100 may be aligned in the same direction. In this case, when mounting the multilayer electronic component 100 on a printed circuit board, the polarity of the terminals of the printed circuit board and the polarity of the external electrodes 131 and 132 of the multilayer electronic component 100 may be unified, thereby improving the expected lifespan of the multilayer electronic component 100.

The Au content (wt %) relative to the total Au and Sn content in the Au—Sn plating layer 132c may be measured, for example, by analyzing the first and second-direction cross-section of the multilayer electronic component 100 polished to the center thereof in the third direction using a scanning electron microscope (SEM)-energy-dispersive X-ray spectroscopy (EDS). However, the present disclosure is not limited thereto, and other known measurement methods may be used.

The Au—Sn plating layer 132c may include at least one of Au₅Sn, AuSn, AuSn₂ or AuSn₄. In more detail, the Au—Sn plating layer 132c may include at least one of Au₅Sn or AuSn, which have a high Au content among the intermetallic compounds between Au and Sn. This allows for a distinct color difference between the Sn plating layer 131c and the Au—Sn plating layer 132c.

It is sufficient for a Sn plating layer 131c to be disposed on the outermost surface of the first external electrode 131, and for an Au—Sn plating layer 132c to be disposed on the outermost surface of the second external electrode 132. The detailed forms of the first and second external electrodes 131 and 132 are not particularly limited.

The first external electrode 131 may include, for example, a first base electrode layer 131a in contact with the first internal electrode 121, and a first nickel plating layer 131b disposed on the first base electrode layer 131a. The second external electrode 132 may include, for example, a second base electrode layer 132a in contact with the second internal electrode 122, and a second nickel plating layer 132b disposed on the second base electrode layer 132a.

The first and second base electrode layers 131a and 132a may be sintered electrode layers each including metal and glass. The first and second base electrode layers 131a and 132a may include at least one selected from the group consisting of Cu, Ni, Pd, Pt, Au, Ag, Pb, and alloys thereof. For example, the first and second base electrode layers 131a and 132a may each include Cu. The glass included in the base electrode layers 131a and 132a may include an oxide of at least one selected from the group consisting of, for example, Ba, Ca, Zn, Al, B, and Si.

The Sn plating layer 131c may be disposed to be in contact with the first Ni plating layer 131b, and the Au—Sn plating layer 132c may be disposed to be in contact with the second Ni plating layer 132b. In an embodiment, the Sn plating layer 131c may be disposed to completely cover the first Ni plating layer 131b, and the Au—Sn plating layer 132c may be disposed to completely cover the second Ni plating layer 132b.

The Sn plating layer 131c may be disposed on the third surface 3 and may extend over portions of the first, second, fifth, and sixth surfaces 1, 2, 5 and 6, and the Au—Sn plating layer 132c may be disposed on the fourth surface 4 and may extend over portions of the first, second, fifth, and sixth surfaces 1, 2, 5 and 6.

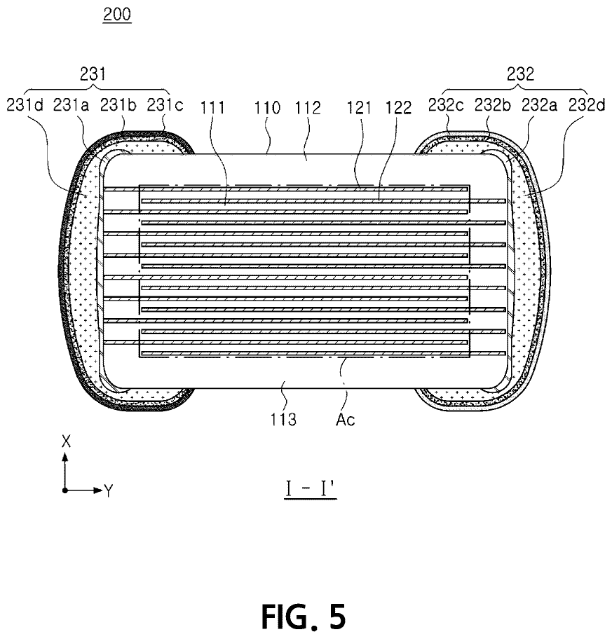

FIG. 5 is a schematic cross-sectional view of a multilayer electronic component 200 according to another embodiment, and is a drawing corresponding to FIG. 2. Hereinafter, the multilayer electronic component 200 according to another embodiment will be described with reference to FIG. 5. For configurations identical or similar to those of the multilayer electronic component 100 described in FIGS. 1 to 4, identical or similar reference numerals are used, and duplicate descriptions will be omitted.

The multilayer electronic component 200 may include a body 110 and external electrodes 231 and 232 disposed on the body 110.

The first external electrode 231 may include a first base electrode layer 231a in contact with the first internal electrode 121, a first conductive resin layer 231d disposed on the first base electrode layer 231a, and a first nickel (Ni) plating layer 231b disposed on the first conductive resin layer 231d.

The second external electrode 232 may include a second base electrode layer 232a in contact with the second internal electrode 122, a second conductive resin layer 232d disposed on the second base electrode layer 232a, and a second nickel (Ni) plating layer 232b disposed on the second conductive resin layer 232d. The Sn plating layer 231c may be disposed to be in contact with the first Ni plating layer 231b, and the Au—Sn plating layer 232c may be disposed to be in contact with the second Ni plating layer 232b.

The first and second base electrode layers 231a and 232a may be sintered electrode layers each including a metal and glass. The first and second base electrode layers 231a and 232a may include at least one selected from the group consisting of Cu, Ni, Pd, Pt, Au, Ag, Pb, and alloys thereof. For example, the first and second base electrode layers 131a and 132a may each include Cu.

The first and second conductive resin layers 231d and 232d may each include metal particles and resin. The metal particles included in the conductive resin layers 231d and 232d may include at least one of spherical particles or flake-shaped particles. In this case, the spherical particles may also include non-perfect spherical shapes, for example, those having a length ratio (major axis/minor axis) of 1.45 or less. The flake-shaped particles refer to particles having a flat and elongated shape, and are not particularly limited, but may have a length ratio (major axis/minor axis) of 1.95 or more. The metal particles included in the conductive resin layers 231d and 232d may include, for example, at least one selected from the group consisting of Cu, Ni, Pd, Pt, Au, Ag, Pb, Sn, and alloys thereof. The resin included in the conductive resin layers 231d and 232d may include at least one of, for example, epoxy resin, acrylic resin, or ethyl cellulose.

### Method of Manufacturing Multilayer Electronic Component

Hereinafter, an example of a method of forming a multilayer electronic component 100 is described. However, the method of manufacturing the multilayer electronic component 100 is not limited to this example.

First, a ceramic powder for forming a dielectric layer 111 is prepared. Ceramic powder may include at least one selected from the group consisting of, for example, BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), Ba(Ti_{1-y}Zr_{y})O₃ (0<y<1), CaZrO₃, and (Ca₁₋ₓSrₓ)(Zr_{1-y}Ti_{y})O₃ (0<x≤0.5, 0<y≤0.5). The BaTiO₃ powder may be synthesized, for example, by reacting a titanium raw material such as titanium dioxide with a barium raw material such as barium carbonate. Methods for synthesizing the ceramic powder include, for example, a solid-state method, a sol-gel method, a hydrothermal synthesis method, and the like, but the present disclosure is not limited thereto. Next, the prepared ceramic powder is dried and ground, and then mixed with an organic solvent such as ethanol and a binder such as polyvinyl butyral to prepare a ceramic slurry. The ceramic slurry is applied to a carrier film and dried to prepare a ceramic green sheet.

Next, a conductive paste for internal electrodes, including metal powder, a binder, an organic solvent and the like, is printed on the ceramic green sheet to a predetermined thickness using a screen printing method, a gravure printing method or the like, thereby forming an internal electrode pattern.

Thereafter, the ceramic green sheet with the internal electrode pattern printed thereon is peeled from the carrier film, and then, a predetermined number of ceramic green sheets with the internal electrode pattern printed thereon are laminated and pressed together to form a ceramic laminate. A predetermined number of ceramic green sheets without the internal electrode pattern may be laminated on the upper and lower portions of the ceramic laminate to form cover portions 112 and 113 after firing. The ceramic laminate is then cut to a predetermined chip size, and the cut chips are sintered to form the body 110. The firing may be performed, for example, in a 1.0% H₂/99.0% N₂ to 3.5% H₂/96.5% N₂ (H₂O/H₂/N₂ atmosphere), at a temperature of 1000° C. to 1400° C. for 1 to 3 hours.

Meanwhile, the margin portions 114 and 115 may be formed by applying and firing a conductive paste for the internal electrode on the ceramic green sheet, except for the area where the margin portion is to be formed. Alternatively, to suppress the step difference caused by the internal electrodes 121 and 122, the ceramic laminate may be cut so that the internal electrode pattern is exposed on both sides of the cut chip in the third direction. Then, a sheet for forming the margin portion may be attached to both sides of the cut chip in the third direction, followed by firing to form the margin portions 114 and 115.

Next, the external electrodes 131 and 132 are formed. For example, the base electrode layers 131a and 132a may be formed by dipping the body 110 in a conductive paste containing metal powder, glass frit, a binder, and an organic solvent, and then firing the conductive paste at a temperature of 500° C. to 900° C. The metal powder may include, for example, Cu powder.

Additionally, nickel plating layers 131b and 132b may be formed on the base electrode layers 131a and 132a using electrolytic plating and/or electroless plating.

Next, a tin (Sn) plating layer 131c may be formed on the first nickel plating layer 131b using electrolytic plating and/or electroless plating.

A Au—Sn plating layer 132c may be formed on the second nickel plating layer 132b. The Au—Sn plating layer 132c may be formed using electrolytic plating using a Au—Sn alloy plating solution containing, for example, at least one selected from the group consisting of Na₃Au(SO₃)₂, Sn(K₂(OH)₆), Na₂SnO₃, NaOH, and the like. For example, increasing the weight ratio of Na₃Au(SO₃)₂ in the Au—Sn alloy plating solution may increase the Au content (wt %) relative to the total Au and Sn content in the Au—Sn plating layer 132c.

On the other hand, a method for manufacturing the multilayer electronic component 200 is not particularly limited. For example, base electrode layers 231a and 232a may be formed on the body 110, and then the body 110 may be dipped in a conductive resin composition containing metal powder, resin, binder, and an organic solvent, followed by a curing heat treatment at a temperature of 250° C. to 550° C. to form the conductive resin layers 231d and 232d.

Next, using the aforementioned method, the Ni plating layers 231b and 232b, the Sn plating layer 231c, and the Au—Sn plating layer 232c may be sequentially formed.

### Multilayer Electronic Component Packaging Unit

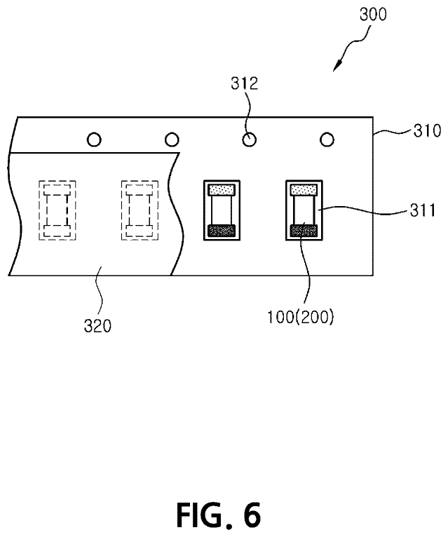

FIG. 6 is a schematic plan view of a multilayer electronic component packaging unit according to an embodiment. Hereinafter, a multilayer electronic component packaging unit 300 according to an embodiment will be described with reference to FIG. 6.

A multilayer electronic component packaging unit 300 according to an embodiment may include a carrier tape 310 and a cover tape 320 attached to the carrier tape 310.

The carrier tape 310 may have, for example, a plurality of receiving grooves 311. The plurality of receiving grooves 311 may accommodate multilayer electronic components 100 (or 200). The plurality of receiving grooves 311 may be arranged along the longitudinal direction of the carrier tape 310.

A plurality of sprocket grooves 312 may be provided on one side of the carrier tape 310. A plurality of sprocket grooves 312 may be arranged along the longitudinal direction of the carrier tape 310. The sprocket grooves 312 may be used to move the carrier tape 310 using a gear-shaped device.

As illustrated in FIG. 6, the two external electrodes of the multilayer electronic component 100 (or 200) may be distinguished from each other through camera recognition during the taping packaging process. Therefore, a plurality of multilayer electronic components 100 (or 200) may be aligned in the same direction within the packaging body 300. In this case, when mounting the multilayer electronic component 100 (or 200) on a printed circuit board, the polarity of the terminal of the printed circuit board and the polarity of the external electrodes 131 and 132 of the multilayer electronic component 100 may be simply unified, thereby improving the expected lifespan of the multilayer electronic components 100 and 200.

### Experimental Example 1

A comparative evaluation of the lifespan was conducted based on voltage application direction changes during screening tests and final use. First, a sample chip having a size of 3216 (length: approximately 3.2 mm, width: approximately 1.6 mm, thickness: approximately 1.6 mm) was prepared. The first external electrode of the sample chip included a first base electrode layer containing Cu, a first Ni plating layer, and an Sn plating layer, sequentially formed. The second external electrode included a second base electrode layer containing Cu, a second Ni plating layer, and an Au—Sn plating layer, sequentially formed.

Next, a burn-in test was performed on the sample chip. The burn-in test was performed four times at 160° C., 75 V, and a 30-minute hold. The voltage application direction for each burn-in test is listed in Table 2 below. After the burn-in test, each sample chip was heat treated at 160° C. for 1 hour.

Finally, each sample chip was mounted on a printed circuit board and subjected to a high-temperature accelerated life test (HALT) at 160° C. and 125 V. The voltage application direction for the high-temperature accelerated life test is listed in Table 2, along with the number of final voltage application direction changes for the sample chips that underwent burn-in test and high-temperature accelerated life test.

In detail, Examples 1 and 2 unified the voltage application direction for the burn-in test as positive (+). In Example 1, the voltage application direction for the high-temperature accelerated life test was unified as positive, while in Example 2, it was changed to negative (−).

Examples 3 and 4 changed the voltage application direction three times for the burn-in test. In Example 3, the voltage application direction for the high-temperature accelerated life test was positive, the initial voltage application direction. In Example 4, the voltage application direction for the high-temperature accelerated life test was negative, the opposite of the initial voltage application direction.

Examples 5 and 6 changed the voltage application direction once for the burn-in test. In Example 5, the voltage application direction in the high-temperature accelerated life test was set to +, which is the initial voltage application direction, and in Example 6, the voltage application direction in the high-temperature accelerated life test was set to negative (−), which is the opposite direction to the initial voltage application direction.

TABLE 2

| Classification | Example 1 | Example 2 | Example 3 | Example 4 | Example 5 | Example 6 |
|---|---|---|---|---|---|---|
| Burn in | + | + | + | + | + | + |
| | + | + | − | − | + | + |
| | + | + | + | + | − | − |
| | + | + | − | − | − | − |
| HALT | + | − | + | − | + | − |
| Number of | 0 | 1 | 4 | 3 | 2 | 1 |
| Changes | | | | | | |

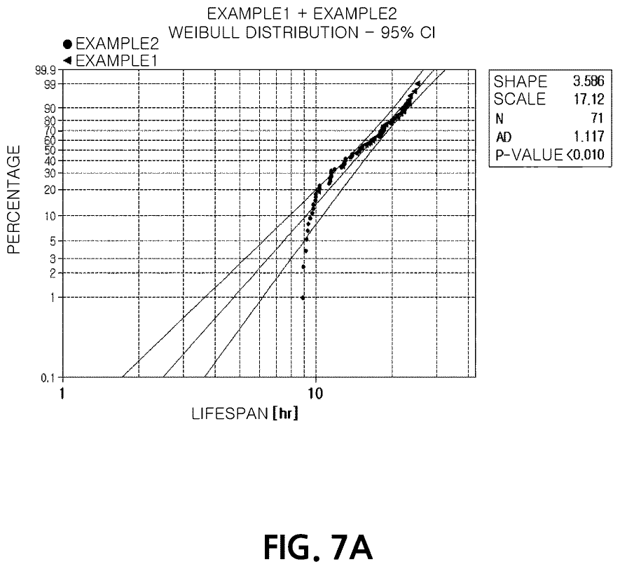

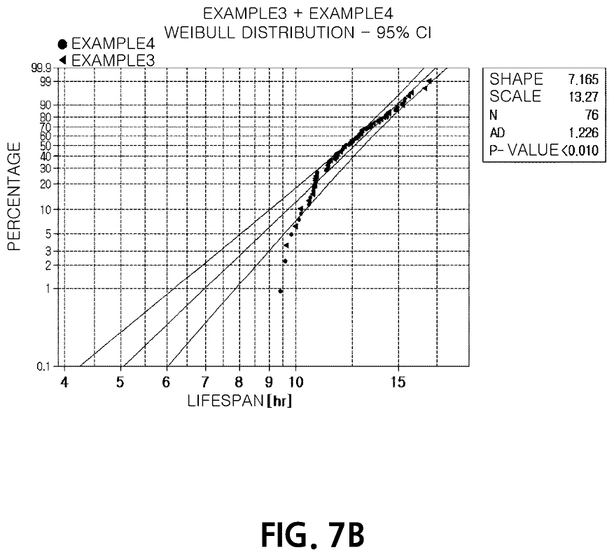

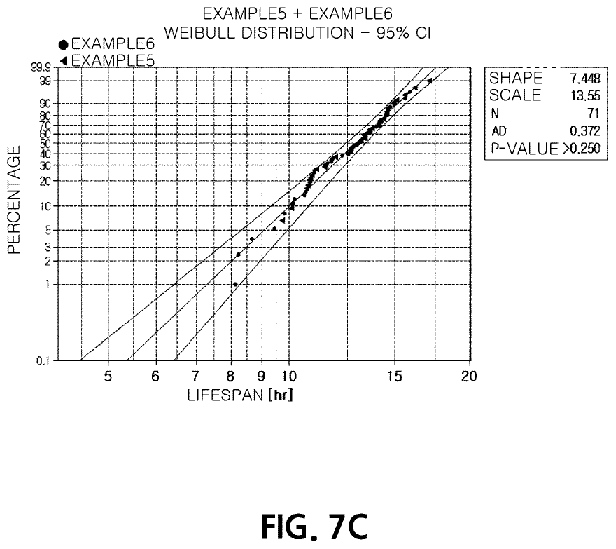

FIG. 7A is a graph illustrating the life Weibull distributions of Examples 1 and 2. FIG. 7B is a graph illustrating the life Weibull distributions of Examples 3 and 4. FIG. 7C is a graph illustrating the life Weibull distributions of Examples 5 and 6. Referring to FIGS. 7A, 7B and 7C, it can be seen that Example 1, which underwent burn-in testing and high-temperature accelerated life test without any change in the voltage application direction, exhibits superior life characteristics compared to Examples 2 to 6.

This is likely due to damage to some domains constituting the dielectric due to voltage applied in the opposite direction to the domain alignment, resulting in a deterioration in insulation resistance of the dielectric.

Furthermore, Example 3 exhibits superior life characteristics compared to Example 4, and Example 5 exhibits superior life characteristics compared to Example 6. This is likely because, while the direction of the initial voltage application and the voltage application direction during the high-temperature accelerated life test were the same in Examples 3 and 5, the direction of the initial voltage application and the voltage application direction during the high-temperature accelerated life test were reversed in Examples 4 and 6. In detail, while the number of changes in voltage application directions is important for maintaining the reliability of multilayer electronic components, it can be confirmed that, it is even more important to unify the direction of the initial voltage applied during the selection process and the application direction of the final voltage applied during use.

### Experimental Example 2

A sample chip having a size of 3216 (length: approximately 3.2 mm, width: approximately 1.6 mm, thickness: approximately 1.6 mm) was prepared. The first external electrode of the sample chip included a first base electrode layer containing Cu, a first Ni plating layer, and an Sn plating layer, sequentially formed. The second external electrode included a second base electrode layer containing Cu, a second Ni plating layer, and an Au—Sn plating layer, sequentially formed.

Subsequently, the taping packaging process was performed for examples in which the Au contents (wt %) relative to the total Au and Sn contents in the Au—Sn plating layers were different. In Example 7, the Au content (wt %) relative to the total Au and Sn content in the Au—Sn plating layer was 14.65 wt %. In Example 8, the Au content (wt %) relative to the total Au and Sn content in the Au—Sn plating layer was 37.3 wt %. In Example 9, the Au content (wt %) relative to the total Au and Sn content in the Au—Sn plating layer was 55.35 wt %. In Example 10, the Au content (wt %) relative to the total Au and Sn content in the Au—Sn plating layer was 62.4 wt %. In the comparative example, an Sn plating layer, rather than an Au—Sn plating layer, was formed on the outermost surface of the second external electrode.

Next, the RGB of the second external electrode was measured and is recorded in Table 3 below. The difference value (b₂*−b₁*) between the b* value (b₁*) of the CIE L*a*b* colorimetric system measured on the Sn plating layer of the first external electrode and the b* value (b₂*) of the CIE L*a*b* colorimetric system measured on the Au—Sn plating layer of the second external electrode was measured and is recorded in Table 3 below.

Subsequently, the taping packaging process was performed on the sample chips of Comparative Example and Examples 7 to 10. 300 sample chips each were packaged, and a camera installed in the packaging equipment was used to determine the colors of the first and second external electrodes, thereby ensuring that the sample chips were arranged in the same direction on the tape. The ratio of the number of sample chips arranged in the same direction on the tape was defined as the “loading rate” and is recorded in Table 3 below.

TABLE 3

| Classi- | Au | | | Loading | Determi- |
|---|---|---|---|---|---|
| fication | (wt %) | RGB | b₂* − b₁* | Rate | nation |
| Comparative | 0 | 245, 245, 247 | −0.77 | 153/300 | X |
| Example | | | | (51%) | |
| Exam- | 14.65 | 244, 243, 238 | 2.03 | 162/300 | X |
| ple 7 | | | | (54%) | |
| Exam- | 37.3 | 249, 247, 222 | 9.86 | 180/300 | X |
| ple 8 | | | | (60%) | |
| Exam- | 55.35 | 255, 255, 202 | 20.37 | 257/300 | Δ |
| ple 9 | | | | (85.7%) | |
| Exam- | 62.4 | 243, 216, 78 | 54.62 | 300/300 | ◯ |
| ple 10 10 | | | | (100%) | |

In the comparative example, the loading rate was approximately 50%, indicating that the sample chips were arranged in a random orientation because it was difficult to distinguish between the first and second external electrodes.

In Examples 7 and 8, the loading rate increased compared to the comparative example, but was lower than in Examples 9 and 10.

In Example 9, the loading rate increased to 85.7%, as the distinction between the first and second external electrodes became easier. In detail, Example 10 satisfied that the Au content (wt %) in the Au—Sn plating layer was 62.4 wt % or more compared to the total content of Au and Sn, thereby clearly distinguishing between the first external electrode and the second external electrode, and thus the loading rate reached 100%.

As set forth above, according to an embodiment, a multilayer electronic component having excellent reliability may be provided.

The present disclosure is not limited by the above-described embodiments and accompanying drawings, but is intended to be limited by the appended claims. Therefore, various forms of substitution, modification and change will be possible by those skilled in the art within the scope of the technical spirit of the present disclosure described in the claims, and this will also be said to fall within the scope of the present disclosure.

In addition, the expression ‘an embodiment’ does not indicate the same embodiment, and is provided to emphasize and describe different unique characteristics. However, the embodiments presented above are not excluded from being implemented in combination with features of another embodiment. For example, even if a matter described in one specific embodiment is not described in another embodiment, it may be understood as a description related to another embodiment, unless there is a description to the contrary or contradicting the matter in another embodiment.

In the present disclosure, the term “connected” includes not only direct connection but also indirect connection through an adhesive layer or the like. Furthermore, the term “electrically connected” includes both physically connected and unconnected cases. In addition, expressions such as first and second are used to distinguish one component from another, and do not limit the order and/or importance of the components. In some cases, without departing from the scope of rights, a first element may be named a second element, and similarly, a second element may be named a first element.

While example embodiments have been shown and described above, it will be apparent to those skilled in the art that modifications and variations could be made without departing from the scope of the present disclosure as defined by the appended claims

What is claimed is:

1. A multilayer electronic component comprising:
a body including a dielectric layer, and a first internal electrode and a second internal electrode disposed alternately with the dielectric layer interposed therebetween; and
a first external electrode and a second external electrode disposed on the body and connected to the first and second internal electrodes, respectively,
wherein the first external electrode comprises a tin (Sn) plating layer disposed on an outermost portion of the first external electrode, and
the second external electrode comprises a gold-tin (Au—Sn) plating layer having a different color from a color of the Sn plating layer, disposed on an outermost of the second external electrode.

2. The multilayer electronic component of claim 1, wherein a Au element content (wt %) relative to total elements of the Au—Sn plating layer is greater than a Sn element content (wt %) relative to the total elements of the Au—Sn plating layer.

3. The multilayer electronic component of claim 1, wherein the Au element content (wt %) relative to a total element content of Au and Sn in the Au—Sn plating layer is 62.4 wt % or more and less than 100 wt %.

4. The multilayer electronic component of claim 1, wherein, when a b* value of a CIE L*a*b* colorimetric system measured from the Sn plating layer is b₁*, and a b* value of the CIE L*a*b* colorimetric system measured from the Au—Sn plating layer is b₂*, b₂*−b₁*≥50 is satisfied.

5. The multilayer electronic component of claim 1, wherein the Au—Sn plating layer includes at least one of Au₅Sn, AuSn, AuSn₂ or AuSn₄.

6. The multilayer electronic component of claim 1, wherein the Au—Sn plating layer includes at least one of Au₅Sn or AuSn.

7. The multilayer electronic component of claim 1, wherein the first external electrode includes a first base electrode layer in contact with the first internal electrode, and a first nickel (Ni) plating layer disposed on the first base electrode layer, and
the second external electrode includes a second base electrode layer in contact with the second internal electrode, and a second nickel (Ni) plating layer disposed on the second base electrode layer.

8. The multilayer electronic component of claim 7, wherein the Sn plating layer is disposed to completely cover the first Ni plating layer, and
the Au—Sn plating layer is disposed to completely cover the second Ni plating layer.

9. The multilayer electronic component of claim 1, wherein the body has a first surface and a second surface opposing each other in a first direction, a third surface and a fourth surface connected to the first and second surfaces and opposing each other in a second direction, and a fifth surface and a sixth surface connected to the first to fourth surfaces and opposing each other in a third direction,
the Sn plating layer is disposed on the third surface and extends onto portions of the first, second, fifth, and sixth surfaces, and
the Au—Sn plating layer is disposed on the fourth surface and extends onto portions of the first, second, fifth, and sixth surfaces.

10. The multilayer electronic component of claim 7, wherein the first and second base electrode layers each include Cu and glass.

11. The multilayer electronic component of claim 1, wherein the first external electrode includes a first base electrode layer in contact with the first internal electrode, a first conductive resin layer disposed on the first base electrode layer, and a first nickel plating layer disposed on the first conductive resin layer, and
the second external electrode includes a second base electrode layer in contact with the second internal electrode, a second conductive resin layer disposed on the second base electrode layer, and a second nickel plating layer disposed on the second conductive resin layer.

12. The multilayer electronic component of claim 11, wherein the first and second base electrode layers each include Cu and glass, and
the first and second conductive resin layers each include metal particles and a resin.

13. The multilayer electronic component of claim 1, wherein a color difference (ΔE) between the Sn plating layer and the Au—Sn plating layer, defined by Mathematical Formula 1, ΔE=[(ΔL*)²+(Δa*)²+(Δb*)²]^{1/2}, is 50 or more, where ΔL* is a difference between L* values of a CIE L*a*b* colorimetric system measured in the Sn plating layer and the Au—Sn plating layer, respectively, Δa* is a difference between a* values of the CIE L*a*b* colorimetric system measured in the Sn plating layer and the Au—Sn plating layer, respectively, and Δb* is a difference between b* values of the CIE L*a*b* colorimetric system measured in the Sn plating layer and the Au—Sn plating layer, respectively.

14. The multilayer electronic component of claim 7, wherein the first and second base electrode layers include at least one selected from the group consisting of Cu, Ni, Pd, Pt, Au, Ag, Pb, and alloys thereof.
